(19) United States
(12) Patent Application Publication
(10) Pub. No.: US 2007/0145600 A1
(43) Pub. Date: Jun. 28, 2007

(54) Semiconductor device and manufacturing method thereof

(76) Inventors: Hisashi Yano, Kyoto (JP); Masakazu Hamada, Osaka (JP); Kazuyoshi Maekawa, Tokyo (JP); Kenichi Mori, Tokyo (JP)

Correspondence Address: MCDERMOTT WILL & EMERY LLP, 600 13TH STREET, NW, WASHINGTON, DC, 20005-3096, US

(21) Appl. No.: 11/646,422

(22) Filed: Dec. 28, 2006

(30) Foreign Application Priority Data
Dec. 28, 2005 (JP) 2005-379320

(51) Int. Cl. H01L 23/48

(52) U.S. Cl. 257/774

(57) ABSTRACT

A semiconductor device includes an embedded wire in a first wire trench formed in a first interlayer dielectric film, the embedded wire having a barrier metal, a first seed film, a second seed film, and a copper film. The first seed film is formed by a copper film containing metal, and the second film is formed by a copper film. The second seed film suppresses that the metal contained in the first seed film diffuses into a wiring material film in a manufacturing process.

### BACKGROUND OF THE INVENTION

1. Field of the Invention The present invention relates to a semiconductor device having a structure of a metal wire provided in a trench and to a manufacturing method of the semiconductor device.

2. Description of the Related Art

In recent years, due to progressing reduction of a wiring pitch in a device, it becomes increasingly important to ensure reliability of wiring. For this purpose, investigations have been made to improve the reliability by adding a variety of elements to copper used as a wiring material.

A manufacturing method of a semiconductor device having a conventional embedded wire will be explained below. FIGS. 3A through 31 are cross sections illustrating a conventional manufacturing method of the semiconductor device.

First, referring to FIG. 3A, a lithography step and an etching step are carried out to form a first wire trench 102 in a first interlayer dielectric film 101, the first interlayer dielectric film 101 being formed of a low dielectric constant material on a substrate (not shown). Next, as a preparatory process, an annealing step is performed on the substrate (semiconductor device) for 60 seconds in a hydrogen atmosphere at a temperature of 280° C. so as to reduce an oxide film formed on a surface of the semiconductor device. Then, as a barrier metal film 103a, a tantalum nitride film having a thickness of 5 nm and a tantalum film having a thickness of 10 nm are sequentially formed on the first interlayer dielectric film 101. In this case, the barrier metal film 103a is a metal film preventing the copper, which is a wiring material, from diffusing into the first interlayer dielectric film 101 provided around the wiring material.

Subsequently, referring to FIG. 3B, a seed film 104a having a thickness of 40 nm is formed on the barrier metal film 103a. In this case, copper containing 1% aluminum is used as a material for the seed film 104a. A purpose of adding aluminum to the material for the seed film 104a is to improve, for example, electromigration resistance and stress migration resistance, and thus to improve the reliability of the semiconductor device.

Next, a copper film 105 is formed on the seed film 104a by using a plating method to fill the first wire trench 102. Then, the copper film, the seed film 104a, and the barrier metal film 103a are polished by chemical mechanical polishing (CMP) such that the barrier metal film 103, the seed film 104, and the copper film 105 remain only in the first wire trench 102 as shown in FIG. 3C. In this way, a first wire is formed.

Next, referring to FIG. 3D, a liner film 106 having a thickness of about 60 nm is formed on the first wire and the first interlayer dielectric film 101. In this case, the liner film 106 prevents the copper included in the wire from diffusing into a second interlayer dielectric film which is to be formed in a later step. The liner film 106 is formed by a silicon nitride film or silicon-carbon film having the relative dielectric constant higher than that of a material for the interlayer dielectric film.

Next, referring to FIG. 3E, a second interlayer dielectric film 107 of a low dielectric constant material is formed on the liner film 106.

Subsequently, referring to FIG. 3F, lithography and etching steps are performed repeatedly in order to form a via hole 108 which reaches the copper film 105 and a second wire trench 109 to which the via hole 108 is open in the second interlayer dielectric film 107.

Next, referring to FIG. 3G, as a preparatory process, an annealing process is performed on the semiconductor device for 60 seconds in a hydrogen atmosphere at a temperature of 280° C. so as to remove an oxide film formed on a surface of the semiconductor device. Then, as a barrier metal film 110a, a tantalum nitride film having a thickness of 5 nm and a tantalum film having a thickness of 10 nm are sequentially formed on inner surfaces of the via hole 108 and the second wire trench 109 and on the second interlayer dielectric film 107.

Subsequently, referring to FIG. 3H, a seed film 111a having a thickness of about 40 nm is formed on the barrier metal film 110a. In this case, as a material for the seed film 111a, copper containing 1% aluminum is used similar to the seed film 104a. A purpose of adding aluminum to the material for the seed film 111a is to improve resistance against, for example, electromigration and stress migration, and thus to improve the reliability of the semiconductor device.

Next, referring to FIG. 3I, a copper film is formed on the seed film 111a by using a plating method to fill the second wire trench 109 and the via hole 108. Then, the barrier metal film 110a, the seed film 111a, and the copper film are polished by CMP such that the barrier metal film 110, the seed film 111, and the copper film 112 remain only in the second wire trench 109 and the via hole 108. In this way, a plug and a second wire are formed.

### SUMMARY OF THE INVENTION

However, the structure of the above-mentioned conventional semiconductor device and the manufacturing method have a problem that the resistance value between a plug and a wire may increase. In such a case, the yield of the semiconductor device decreases.

FIG. 4 shows the cumulative frequency distribution of via resistance values in a case where wires embedded in multiple layers are formed according to the conventional method.

It should be designed that all of the via resistance values are 2×10⁷Ω or lower. However, the FIG. 4 shows that the via resistance values are broadly distributed and the via resistance increases. The inventors of the present invention carried out various investigations as to the cause of the increased via resistance and as a result found that the increased via resistance is attributable to an aluminum oxide film which is formed on a copper wire but not sufficiently removed.

FIG. 5 is a cross section illustrating a mechanism which is considered a cause of the increased resistance between the wire and the plug in the conventional method. In the conventional manufacturing method, heating after the formation of the first wire distributes aluminum included in the seed film 104a in the copper film 105, which forms a copper-aluminum alloy. Especially, it is considered that after the via hole 108 is formed, aluminum included in the seed film 104a bonds with atmospheric oxygen, so that not only a copper oxide film but also an aluminum oxide film are formed on upper surface of the copper film 105 and on upper end surfaces of the seed film 104. The aluminum oxide film can not be reduced in an annealing process in the hydrogen atmosphere performed before the formation of the barrier metal film 110a, because the aluminum oxide film has the intermolecular bond energy significantly stronger than that of the copper oxide film. For this reason, it can be considered that an aluminum oxide film 113 formed on the first wire can not be removed, so that the resistance value between the wire and the plug increases.

An object of the invention is to provide a semiconductor device without the above-mentioned problems, the semiconductor device being manufactured with a good yield and having high reliability and another object of the invention is to provide a manufacturing method of such semiconductor device.

In order to solve the above-mentioned problems, investigations have been carried out, and it turned out that a metal added to a seed film forms an oxide on the upper surface of a wiring material (copper film) but the oxide is not sufficiently removed. To cope with this problem, the invention includes the step of removing the metal oxide film.

That is, the semiconductor device according to the present invention includes: a first interlayer dielectric film on a substrate, the first interlayer dielectric film having a trench; a first wire in the trench of the first interlayer dielectric film; a second interlayer dielectric film on the first wire and the first interlayer dielectric film; and a plug and a second wire in the second interlayer dielectric film, the plug and the second wire being formed above the first wire, wherein the first wire includes: a first metal film covering the trench, the first metal film including copper and a metal which has binding energy with oxygen higher than that of the copper; a second metal film provided on the first metal film to cover the trench, the second metal film including a metal which has binding energy with oxygen lower than that of the first metal film; and a copper film provided on the second metal film to fill the trench, and wherein the semiconductor device further includes a metal oxide film on upper end surfaces of the first metal film and second metal film and an upper surface of the copper film.

In this structure, the second metal film containing metal having the binding energy with oxygen lower than that of the first metal film is provided between the first metal film and the copper film. Metal having the binding energy with oxygen lower than that of the first metal film is diffused from the first metal film into the copper film by a thermal treatment performed in a manufacturing process. However, in this structure, it is possible to reduce the amount of the metal having the binding energy with oxygen lower than that of the first metal film. As a result, it is possible to reduce a thickness of the metal oxide film to be formed by the thermal treatment on the upper surface of the copper film compared to the conventional structure, and it is possible to reduce the resistance value between the plug and the wire.

The semiconductor device manufacturing method of the present invention comprising the steps of: (a) forming a first wire in a trench formed in a first interlayer dielectric film; (b) forming a second interlayer dielectric film on the first wire and the first interlayer dielectric film; and (c) forming a plug and a second wire in the second interlayer dielectric film on the first wire; wherein step (a) includes: (a1) forming a first metal film to cover the trench, the first metal film containing copper and a metal which has binding energy with oxygen higher than that of the copper; (a2) forming a second metal film on the first metal film to cover the trench, the second metal film containing a metal which has binding energy with oxygen lower than that of the first metal film; and (a3) forming a copper film on the second metal film to fill the trench, and wherein before step (c), a metal oxide film is formed on upper end surfaces of the first metal film and second metal film and on an upper surface of the copper film, and a film thickness of the metal oxide film is thinner on the upper surfaces of the copper film and second metal film than on the upper end surfaces of the first metal film.

In this method, it is possible to improve stress migration resistance and electromigration resistance by adding metal having the binding energy with oxygen higher than that of the copper to a material for the first metal film, and at the same time, it is possible to suppress the formation of the metal oxide film on the upper surface of the copper film by suppressing the diffusion of the metal added to the material for the first metal film. By this method, it is possible to reduce the resistance between the plug and the copper film, so that it is possible to manufacture semiconductor device with improved reliability and with a good yield.

### BRIEF DESCRIPTION OF THE DRAWINGS

FIGS. 1A through 1H are cross sections illustrating a semiconductor device manufacturing method according to an embodiment of the present invention.

FIG. 2 is a cross section illustrating a semiconductor device according to the embodiment of the present invention.

FIGS. 3A through 3H are cross sections illustrating a conventional semiconductor device manufacturing method.

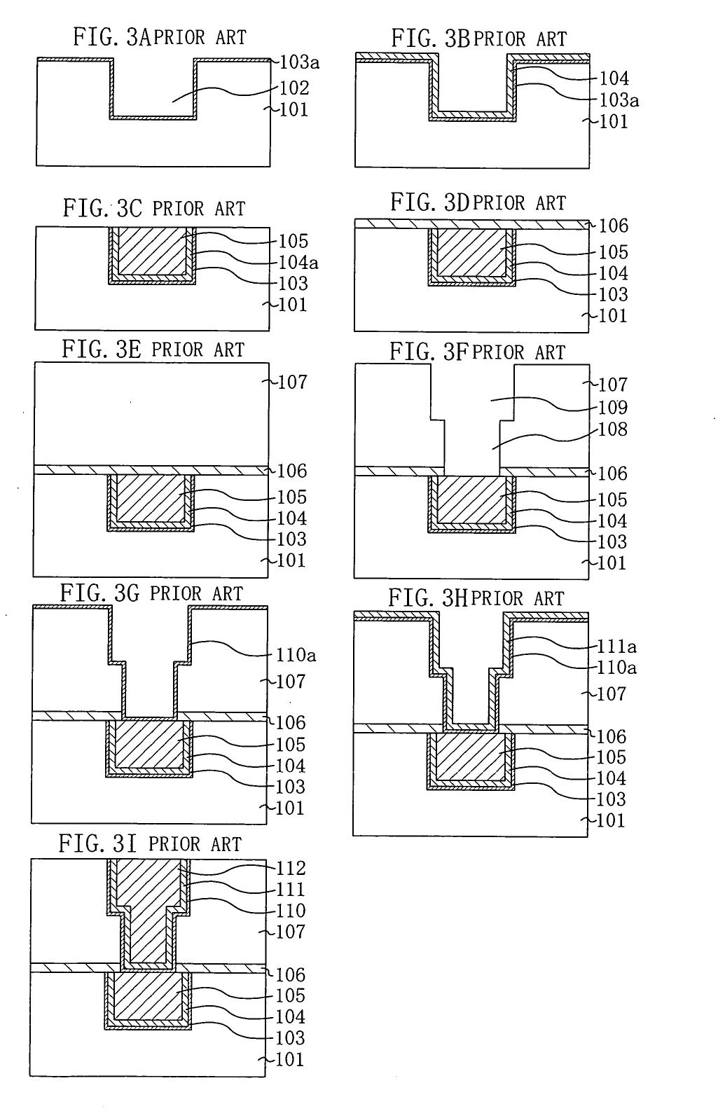

FIG. 4 is a diagram illustrating cumulative frequency distribution of via resistance values of conventional embedded wires.

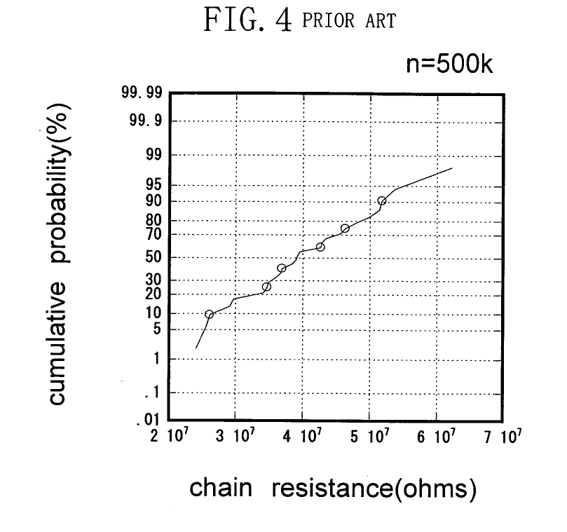

FIG. 5 is a cross section illustrating a conventional mechanism increasing the via resistance.

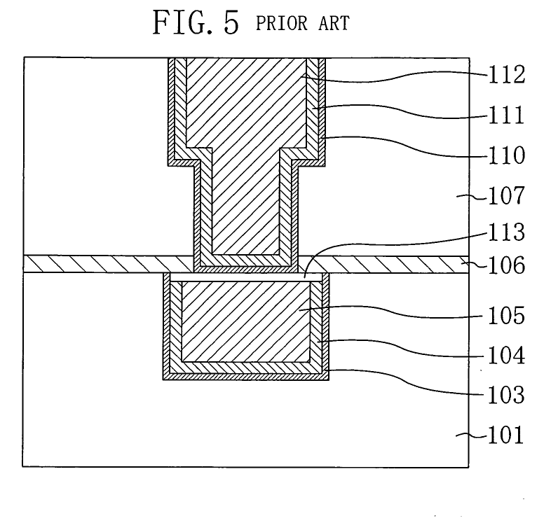

### DESCRIPTION OF THE PREFERRED EMBODIMENTS

### Embodiment

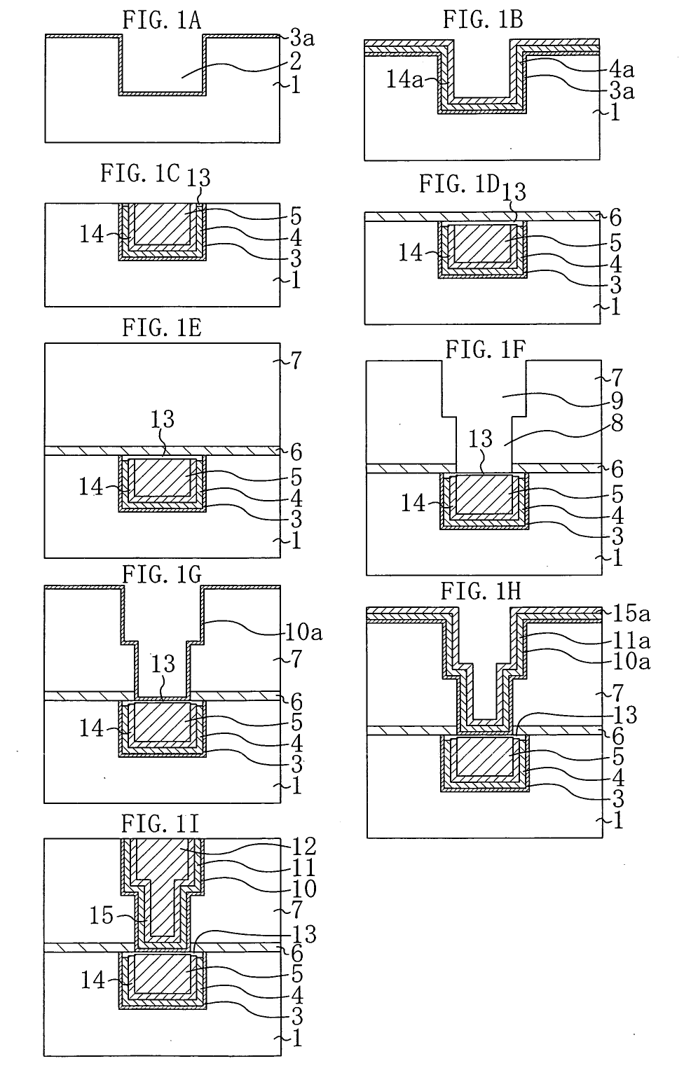

FIGS. 1A through 1I are cross sections illustrating a semiconductor device manufacturing method according to an embodiment of the present invention.

First, referring to FIG. 1A, a lithography step and an etching step is performed so as to form a first wire trench 2 in a first interlayer dielectric film 1, the first interlayer dielectric film 1 being formed of a low dielectric constant material on a substrate (not shown). Next, as a preparatory process, an annealing process is performed on the substrate (semiconductor device) for 60 seconds in a hydrogen atmosphere at a temperature of 280° C. so as to reduce an oxide film formed on a surface of the semiconductor device. Then, as a barrier metal film 3a, a tantalum nitride film having a thickness of 5 nm and a tantalum film having a thickness of 10 nm are formed on the first interlayer dielectric film 1 by, for example, sputtering. In this case, the barrier metal film 3a is a metal film preventing the copper, which is a wiring material, from diffusing into the first interlayer dielectric film 1 provided around the wiring material.

Subsequently, referring to FIG. 1B, a seed film 4a having a thickness of 20 nm is formed on the barrier metal film 3a by sputtering. In this case, copper containing 1% aluminum by weight is used as a material for the seed film 4a. A purpose of adding aluminum to the seed film 4a is to improve, for example, electromigration resistance and stress migration resistance, and thus to improve the reliability of the semiconductor device. Subsequently, a seed film 14a having a thickness of 20 nm is formed on the seed film 4a by, for example, sputtering. As a material for the seed film 14a, copper containing no impurity metal, such as aluminum, is used.

Next, a copper film is formed on the seed film 14a by using a plating method to fill the first wire trench 2. Then, the copper film, the seed film 4a, and the barrier metal film 3 are polished by CMP such that the barrier metal film 3, the seed film 4, the seed film 14, and the copper film 5 remain only in the first wire trench 2 as shown in FIG. 1C. In this way, a first wire is formed. In the step of forming the first wire, an aluminum oxide film 13 including a thin Al₂O₃ film is formed on upper end surfaces of the seed film 4.

Next, referring to FIG. 1D, a liner film 6 having a thickness of about 60 nm is formed on the first wire and the first interlayer dielectric film 1 by CVD. In this case, the liner film 6 prevents the copper included in the first wire from diffusing into a second interlayer dielectric film which is to be formed in a later step. The liner film 6 is formed by, for example, a silicon-carbon film or silicon nitride film having the relative dielectric constant higher than that of a material for the interlayer dielectric film. Note that, heating during the formation of the liner film 6 causes aluminum included in the seed film 4 to diffuse into the upper end surfaces of the seed film 14 and the vicinity of an upper surface of the copper film 5. Therefore, the aluminum oxide film 13 is also formed on the upper surface of the copper film 5, although the aluminum oxide film 13 on the upper surface of the copper film 5 is very thin. Moreover, a thin copper oxide film (not shown) is also formed on the upper end surfaces of the seed film 4 and the seed film 14 and on the upper surface of the copper film 5.

Next, referring to FIG. 1E, a second interlayer dielectric film 7 of a low dielectric constant material is formed on the liner film 6 by using, for example, CVD. Heating during the formation of the second interlayer dielectric film 7 diffuses aluminum included in the seed film 4 further into the seed film 14 and the copper film 5.

Subsequently, referring to FIG. 1F, lithography and etching steps are performed repeatedly in order to form a via hole 8 reaching the copper film 5 and a second wire trench 9 to which the via hole 8 is open in the second interlayer dielectric film 7. Moreover, an opening 18 is formed in the liner film 6. In this case, without the seed film 14, the diffusion of aluminum included in the seed film 4 would advance, and a thick aluminum oxide film would be formed on the upper surface of the copper film 5 when the upper surface of the copper film 5 is exposed as a result of forming the via hole 8. However, in the method of the embodiment, the seed film 14 is provided, and thus the aluminum oxide film 13 formed on the upper surface of the copper film 5 is significantly thinner compared to a case where the seed film 14 is not provided. When the copper film 5 is exposed, a thin copper oxide film (not shown) is also formed on the upper surface of the copper film 5. Then, as a preparatory process, an annealing process is performed on the semiconductor substrate for 60 seconds in a hydrogen plasma atmosphere at a temperature of 280° C. so as to remove the aluminum oxide film 13 and the copper oxide film formed on the surface of the semiconductor device.

Next, referring to FIG. 1G, a tantalum nitride film having a thickness of 5 nm and a tantalum film having a thickness of 10 nm are sequentially formed as a barrier metal film 10a.

Subsequently, referring to FIG. 1H, a seed film 11a having a thickness of about 20 nm is formed on the barrier metal film 10a by, for example, sputtering. As a material for the seed film 11a, copper containing 1% aluminum by weight is used. A purpose of adding aluminum to the material for the seed film 11a is to improve, for example, electromigration resistance and stress migration resistance, and thus to improve the reliability of the semiconductor device. Subsequently, a seed film 15a having a thickness of 20 nm is formed on the seed film 11a by, for example, sputtering. Similar to the seed film 14, the seed film 15a does not contain element such as aluminum.

Next, referring to FIG. 1I, a copper film is formed on the seed film 15a by using a plating method such that the copper film fills the second wire trench 9 and the via hole 8. Then, CMP is performed to polish the barrier metal film 10a, the seed film 11a, the seed film 15a, and the copper film in order to expose an upper surface of the second interlayer dielectric film 7. As a result, a second line including the barrier metal film 10, the seed films 11 and 15, and the copper film 12 are formed, wherein the barrier metal film 10, the seed films 11 and 15, and the copper film 12 are provided on inner surfaces of the second wire trench 9, the via hole 8, and the opening 18. In this way, an embedded wire according to the embodiment is formed.

As described above, in the conventional wire formation method, the resistance between the wire and the plug increases, because the aluminum oxide film formed on the copper wire is not removed sufficiently.

Compared to the conventional wire formation method, in the manufacturing method of this embodiment, the seed film 14 which does not contain aluminum is formed on the seed film 4 containing aluminum. A thermal treatment performed after the formation of the first wire diffuses the aluminum into the copper film 5. However, in the semiconductor device manufactured according to the manufacturing method mentioned above, it is possible to significantly reduce the amount of the aluminum diffused into the copper film 5 compared to the conventional semiconductor device. Therefore, a thickness of the aluminum oxide film 13 is thinner on the upper end surfaces of the seed film 14 and on the surface of the copper film 5 than on the upper end surfaces of the seed film 4. Especially, part of the aluminum oxide film 13 is removed by an annealing treatment in the step illustrated with FIG. 1F. Therefore, the aluminum oxide film 13 extending over the copper film 5 is very thin.

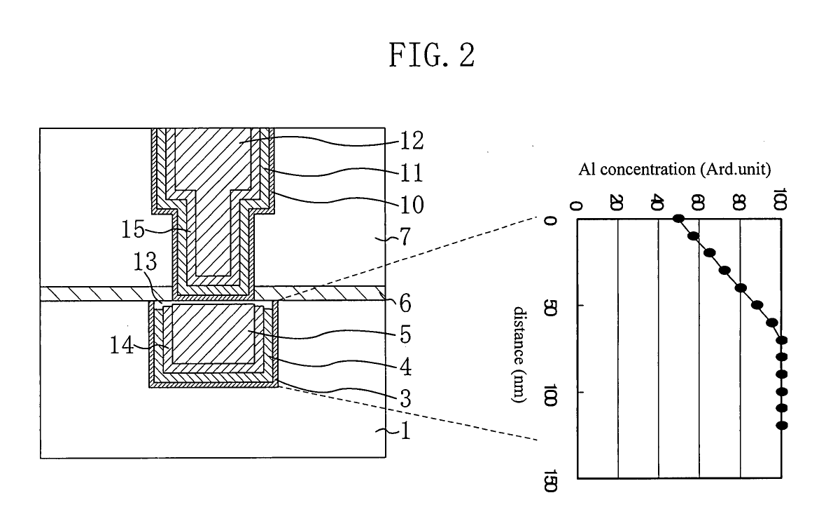

FIG. 2 is a cross section of the device of the embodiment, with which the characteristics of the semiconductor device manufacturing method of the embodiment are described. As shown in a diagram in FIG. 2, the aluminum concentration in the copper film 5 can be reduced more in an upper part of the wire (at the bottom of the via) than in a lower part of the wire. As a result, it is possible to reduce the thickness of the aluminum oxide film 13 on the copper film 5 compared to the conventional semiconductor device. Therefore, it is possible to improve the electromigration resistance and the stress migration, and at the same time, it is possible to suppress the resistance value between the wire and the plug within an acceptable range.

The embodiment is explained with reference to the example where re-sputtering is not performed after the barrier metal film 10a of the second wire is formed. However, after the barrier metal film 10a is formed in the process illustrated with FIG. 1G, the re-sputtering process may be performed to remove the Al oxide film 13 formed on the copper film of the first wire. The re-sputtering process thickens the barrier metal film 10a in the via hole 8, which can also improve electromigration resistance and stress migration resistance.

Moreover, before the formation of the barrier metal 10a, a hydrogen plasma process may be performed to remove the aluminum oxide film 13.

In the description above, an example where two embedded wires are formed has been explained. However, repeating the similar wire formation step can form wires in multiple layers.

As shown in FIG. 11, the semiconductor device manufactured according to the manufacturing method of the embodiment includes: the first interlayer dielectric film 1 on the substrate formed of silicon, the first interlayer dielectric film 1 including the low dielectric constant material which has the first wire trench 2; the barrier metal film 3 in the first wire trench 2, the barrier metal film 3 being formed by, for example, the tantalum nitride film and the tantalum film; the seed film 4 on the barrier metal film 3, the seed film 4 being formed of copper containing, for example, 1% aluminum by weight; the seed film 14 on the seed film 4, the seed film 14 formed of copper; the copper film 5 on the seed film 14, the copper film 5 being provided in the first wire trench 2; the liner film 6 on the first interlayer dielectric film 1, the liner film 6 being formed by a dielectric film which has the opening 18 formed in a region over the copper film 5; and the aluminum oxide film 13 on upper end surfaces of the seed films 4 and 14 and on an upper surface of the copper film 5, a film thickness of the aluminum oxide film 13 is thinner on the upper surface of the copper film 5 than on the upper end surfaces of the seed film 14. The semiconductor device according to the embodiment further includes: the second interlayer dielectric film 7 including the low dielectric constant material in which the via hole 8 and the second wire trench 9 are formed, one end of the via hole 8 being open to the opening 18 of the liner film 6 and the other end of the via hole 8 being open to the second wire trench 9; the barrier metal film 10 in the second wire trench 9, the via hole 8, and the opening 18, the barrier metal film 10 being formed by, for example, the tantalum nitride film and the tantalum film; the seed film 11 on the barrier metal film 10, the seed film 11 including copper which contains, for example, 1% aluminum by weight; the seed film 15 on the seed film 11, the seed film being formed of copper; and the copper film 12 on the seed film 15, 5 the copper film 12 being provided in the second wire trench 9, the via hole 8, and the opening 18. The thin copper oxide film (not shown) which does not affect the performance is formed on the upper end surfaces of the seed films 4 and 11 and on the surface of the copper film 5. The width of the second wire trench is, for example, 0.1 μm and the depth is, for example, 0.15 μm.

The semiconductor device of the embodiment is explained with reference to an example where aluminum is added to a material for the lower seed film 4. However, any metal, such as Mg, Zn, Fe, Sn, or Ti, having the binding energy with oxygen higher than that of the copper may be added to the copper. More than one element of metal which has the binding energy with oxygen higher than that of the copper may be added to the seed film material (e.g., copper).

Moreover, in the semiconductor device of the embodiment, metal other than copper is not added to materials for the upper seed film 15 and the lower seed film 14. However, the material for the seed films 4 and 14 may contain metal, such as Ag or Au, having the binding energy with oxygen same or lower than that of the copper.

The embedded wire structure of the present invention described above is applicable to, for example, general semiconductor integrated circuits.

What is claimed is:

1. A semiconductor device comprising:
a first interlayer dielectric film on a substrate, the first interlayer dielectric film having a trench,
a first wire in the trench of the first interlayer dielectric film,
a second interlayer dielectric film on the first wire and the first interlayer dielectric film, and
a plug and a second wire in the second interlayer dielectric film, the plug and the second wire being formed above the first wire,
wherein the first wire includes:
a first metal film covering the trench, the first metal film including copper and a metal which has binding energy with oxygen higher than that of the copper,
a second metal film provided on the first metal film to cover the trench, the second metal film including a metal which has binding energy with oxygen lower than that of the first metal film, and
a copper film provided on the second metal film to fill the trench, and
wherein the semiconductor device further includes a metal oxide film on upper end surfaces of the first metal film and second metal film and an upper surface of the copper film.

2. A semiconductor device of claim 1, wherein the second metal film is a copper film.

3. A semiconductor device of claim 2, wherein the second metal film further contains Ag or Au.

4. A semiconductor device of claim 1, wherein the metal having the binding energy with oxygen higher than that of the copper is any one of Al, Mg, Zn, Fe, Sn, and Ti.

5. A semiconductor device of claim 1, wherein the metal oxide film includes:
an oxide film of the metal which has the binding energy with oxygen higher than that of the copper, and
a copper oxide film.

6. A semiconductor device of claim 1, wherein the first wire further includes a barrier metal film provided between the first interlayer dielectric film and the first metal film to covering the trench.

7. A semiconductor device of claim 1, wherein a film thickness of the metal oxide film is thinner on the upper surfaces of the copper film and second metal film than on the upper end surface of the first metal film.

8. A semiconductor device of claim 1, further comprising:
a liner dielectric film between the first interlayer dielectric film and the second interlayer dielectric film, the liner dielectric film having an opening over the first wire,
wherein the plug is provided in the opening.

9. A semiconductor device of claim 1, in the first wire, a concentration of the metal having the binding energy with oxygen higher than that of the copper is lower in the second metal film than in the first metal film.

10. A semiconductor device manufacturing method comprising the steps of:
(a) forming a first wire in a trench formed in a first interlayer dielectric film,
(b) forming a second interlayer dielectric film on the first wire and the first interlayer dielectric film, and
(c) forming a plug and a second wire in the second interlayer dielectric film on the first wire,
wherein step (a) includes:
(a1) forming a first metal film to cover the trench, the first metal film containing copper and a metal which has binding energy with oxygen higher than that of the copper,
(a2) forming a second metal film on the first metal film to cover the trench, the second metal film containing a metal which has binding energy with oxygen lower than that of the first metal film, and (a3) forming a copper film on the second metal film to fill the trench, wherein before step (c), a metal oxide film is formed on upper end surfaces of the first metal film and second metal film and on an upper surface of the copper film, and a film thickness of the metal oxide film is thinner on the upper surfaces of the copper film and second metal film than on the upper end surfaces of the first metal film.

11. A semiconductor device manufacturing method of claim 10, wherein the second metal film is a copper film.

12. A semiconductor device manufacturing method of claim 11, wherein the second metal film further contains Ag or Au.

13. A semiconductor device manufacturing method of claim 10, wherein the metal oxide film includes:
an oxide film of the metal which has the binding energy with oxygen higher than that of the copper, and
a copper oxide film.
